(19) United States
(12) Patent Application Publication
(10) Pub. No.: US 2025/0349536 A1
(43) Pub. Date: Nov. 13, 2025

(54) SEMICONDUCTOR STRUCTURE AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/897,622

(22) Filed: Sep. 26, 2024

(30) Foreign Application Priority Data
May 11, 2024 (CN) 202410584935.2

(51) Int. Cl. H01L 21/02

(52) U.S. Cl. CPC H01L 21/02381; H01L 21/02433

(57) ABSTRACT

A semiconductor structure includes: a miscut angle substrate; a mask layer located on a side of the miscut angle substrate, where the mask layer includes a through hole penetrating through the mask layer; and an epitaxial layer, where at least part of the epitaxial layer is located in the through hole. The technical solutions of the present disclosure may reduce a dislocation density of the semiconductor structure, improve a crystal quality, and improve characteristics of a semiconductor device.

### CROSS-REFERENCE TO RELATED APPLICATIONS

The present application claims priority to Chinese Patent Application No. 202410584935.2, filed on May 11, 2024, which is hereby incorporated by reference in its entirety.

### TECHNICAL FIELD

The present disclosure relates to the field of semiconductor technologies, and in particular, to a semiconductor structure and a manufacturing method for the semiconductor structure.

### BACKGROUND

With a development of science and technology, group III-V compound semiconductors are typically represented by gallium nitride (GAN), gallium arsenide (GaAs) and indium phosphide (InP), which gradually become a current research hotspot, and are suitable for manufacturing high-speed, high-frequency, high-power and light-emitting electronic devices, and thus have a wide application prospect.

Epitaxial growth of a group III-V compound on a substrate still has many problems to be solved, for example, due to existence of a lattice mismatch, a polarity effect/non-polarity effect, a large thermal expansion coefficient difference between materials and the like, dislocation of

heteroepitaxy is easily caused, and the dislocation is mainly a line dislocation of crystal direction. Moreover, when a thickness of a group III-V compound semiconductor film layer reaches a critical value, cracking is prone to occur, resulting in degradation and failure of device performance.

### SUMMARY

In view of this, embodiments of the present disclosure provide a semiconductor structure and a manufacturing method therefor to solve a technical problem of a high number of dislocations in a semiconductor film layer in a related art.

According to an aspect of the present disclosure, a semiconductor structure is provided.

The semiconductor structure includes: a miscut angle substrate; a mask layer located on a side of the miscut angle substrate, where the mask layer includes a through hole penetrating through the mask layer; and an epitaxial layer, where at least part of the epitaxial layer is located in the through hole.

According to another aspect of the present disclosure, a manufacturing method for a semiconductor structure is provided. The manufacturing method for the semiconductor structure includes: manufacturing a mask layer on a side of a miscut angle substrate; etching the mask layer to form a through hole penetrating through the mask layer; and manufacturing an epitaxial layer from the through hole.

### BRIEF DESCRIPTION OF THE DRAWINGS

FIG. 1 is a schematic structural diagram of a semiconductor structure according to an embodiment of the present disclosure.

FIG. 2 is a schematic diagram of a three-dimensional structure of a miscut angle substrate and a mask layer in FIG. 1.

FIG. 3 is a schematic diagram of another three-dimensional structure of a miscut angle substrate and a mask layer in FIG. 1.

FIG. 4 is a schematic structural diagram of a semiconductor structure according to another embodiment of the present disclosure.

FIG. 5 is a schematic structural diagram of a semiconductor structure according to another embodiment of the present disclosure.

FIG. 6 is a schematic structural diagram of a semiconductor structure according to another embodiment of the present disclosure.

FIG. 7 is a schematic structural diagram of a semiconductor structure according to another embodiment of the present disclosure.

FIG. 8 is a schematic structural diagram of a semiconductor structure according to another embodiment of the present disclosure.

FIG. 9 is a schematic structural diagram of a semiconductor structure according to another embodiment of the present disclosure.

FIG. 10 is a schematic structural diagram of a semiconductor structure according to another embodiment of the present disclosure.

FIG. 11 is a schematic structural diagram of a semiconductor structure according to another embodiment of the present disclosure.

FIG. 12 is a schematic structural diagram of a semiconductor structure according to another embodiment of the present disclosure.

FIG. 13 is a schematic structural diagram of a semiconductor structure according to another embodiment of the present disclosure.

FIG. 14 is a schematic structural diagram of a semiconductor structure according to another embodiment of the present disclosure.

FIG. 15 is a schematic flowchart of a manufacturing method for a semiconductor structure according to an embodiment of the present disclosure.

FIG. 16 to FIG. 20 are schematic structural diagrams of intermediate structures in a manufacturing method for a semiconductor structure according to an embodiment of the present disclosure.

### DETAILED DESCRIPTION OF THE EMBODIMENTS

Technical solutions in embodiments of the present disclosure are described clearly and completely below with reference to the accompanying drawings of the embodiments of the present disclosure. Apparently, the described embodiments are only a part, but not all of the embodiments of the present disclosure.

In order to reduce a dislocation density of a semiconductor structure, the present disclosure provides following technical solutions.

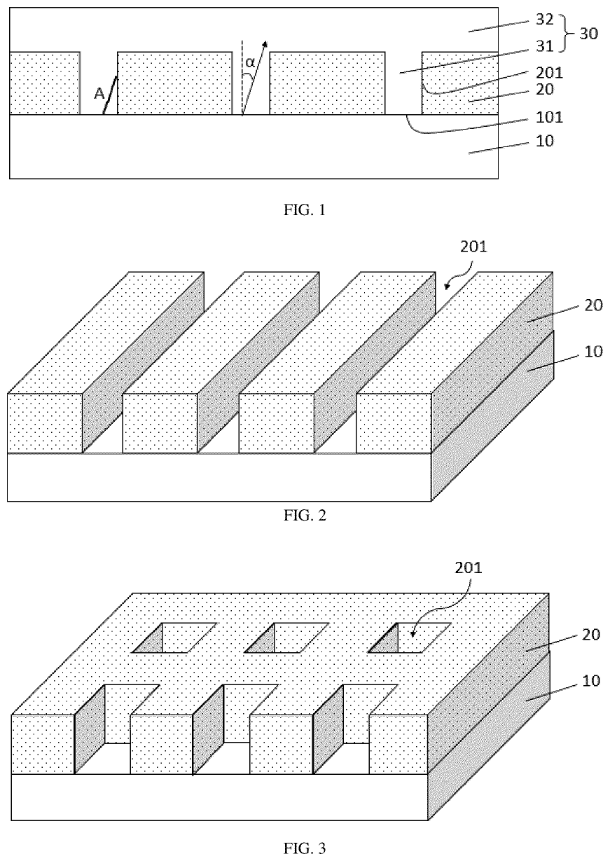

FIG. 1 is a schematic structural diagram of a semiconductor structure according to an embodiment of the present disclosure. As shown in FIG. 1, the semiconductor structure includes: a miscut angle substrate 10; a mask layer 20 located on a side of the miscut angle substrate 10, where the mask layer 20 includes a through hole 201 penetrating through the mask layer; and an epitaxial layer 30, where at least part of the epitaxial layer 30 is located in the through hole 201.

Specifically, as shown in FIG. 1, the mask layer 20 is located on a side of the miscut angle substrate 10, the through hole 201 penetrates through the mask layer 20, and the epitaxial layer 30 is epitaxially grown from the miscut angle substrate 10 exposed by the through hole 201. Since the substrate is a material having a miscut angle, a part of dislocations in the epitaxial layer, such as a dislocation A, deviates from an extending direction of the through hole and is terminated at a sidewall of the through hole, thereby reducing a dislocation density of the semiconductor structure. For example, the miscut angle substrate is monocrystalline silicon, a surface of which is a (111) crystal plane with a miscut angle, and a normal direction of the (111) crystal plane deviates from the extending direction of the through hole. A threading dislocation generally extends along a C-axis direction, that is, the dislocation A extends along the normal direction of the (111) crystal plane, and therefore, as the epitaxial layer grows in the through hole, the dislocation A gradually deviates from the extending direction of the through hole and is terminated at the sidewall of the through hole, thereby reducing a dislocation density of the semiconductor structure.

It should be noted that the extending direction of the through hole refers to a line connecting center points of all cross-sections of the through hole in a direction parallel to a plane where the miscut angle substrate is located.

Optionally, FIG. 2 is a schematic diagram of a three-dimensional structure of a miscut angle substrate and a mask layer in FIG. 1, and as shown in FIG. 2, a shape of a projection, on the miscut angle substrate 10, of a through hole 201 is strip-shaped. FIG. 3 is a schematic diagram of another three-dimensional structure of a miscut angle substrate and a mask layer in FIG. 1, and as shown in FIG. 3, a shape of a projection, on the miscut angle substrate 10, of a through hole 201 is square. Optionally, a shape of a projection, on the miscut angle substrate, of a through hole is circular, hexagonal, or other shapes, and a person skilled in the art may set a shape of the through hole according to actual requirements.

In an embodiment, as shown in FIG. 1, the miscut angle substrate 10 includes a first exposed surface 101 exposed by the through hole 201, the first exposed surface 101 has a miscut angle α, and the miscut angle α ranges from 0.1 degrees to 20 degrees. Specifically, when the miscut angle α is properly increased, an angle of the dislocation A deviating from the extending direction of the through hole may be increased, and a possibility that the dislocation terminates at the sidewall of the through hole is improved, thereby further reducing the dislocation density of the semiconductor structure. Optionally, the miscut angle α is not greater than 20 degrees. However, an excessive miscut angle α (for example, the miscut angle α is greater than 30 degrees) may cause a change in the crystal plane of the first exposed surface, resulting in a decrease in an epitaxial rate.

Optionally, the miscut angle α ranges from 0.2 degrees to 8 degrees. Specifically, due to physical characteristics of the substrate and a semiconductor material, a small-angle miscut angle α may further improve the dislocation density. Optionally, the miscut angle α is 0.2 degrees, 0.8 degrees, 1 degree, 2 degrees, 4 degrees or 8 degrees, and a person skilled in the art may select an appropriate inclination angle value according to actual requirements. For example, when the miscut angle substrate is sapphire, the miscut angle is 0.2 degrees; and when the miscut angle substrate is GaN or SiC, the miscut angle is 4 degrees.

In an embodiment, when the miscut angle substrate 10 is monocrystalline silicon, monocrystalline germanium, or monocrystalline silicon germanium, the first exposed surface 101 has a miscut angle α deviating from the (111) crystal plane. Alternatively, when the miscut angle substrate 10 is monocrystalline silicon carbide or sapphire, the first exposed surface 101 has a miscut angle α deviating from the (0001) crystal plane. Specifically, the (111) crystal planes of monocrystalline silicon, monocrystalline germanium and monocrystalline silicon germanium, as well as the (0001) crystal planes of monocrystalline silicon carbide and sapphire, are more beneficial to subsequent epitaxial growth of the epitaxial layers 30.

It should be noted that, for example, when the miscut angle substrate 10 is monocrystalline silicon, monocrystalline germanium or monocrystalline silicon germanium, the first exposed surface 101 has α miscut angle α deviating from the crystal plane (111), a plane where the first exposed surface 101 is located is the plane where the miscut angle substrate 10 is located, and the α is an angle difference between the plane where the miscut angle substrate 10 is located and the (111) crystal plane.

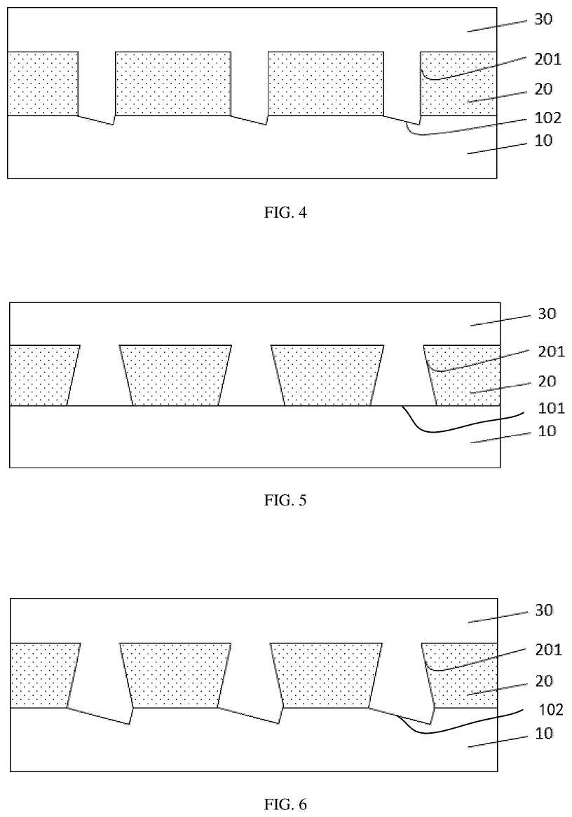

In an embodiment, FIG. 4 is a schematic structural diagram of a semiconductor structure according to another embodiment of the present disclosure, as shown in FIG. 4, a miscut angle substrate 10 is monocrystalline silicon, monocrystalline germanium, or monocrystalline silicon germanium, the miscut angle substrate 10 includes a second exposed surface 102 exposed by a through hole 201, and a crystal plane of the second exposed surface 102 is a (111) crystal plane. Specifically, a surface of the miscut angle substrate 10 is etched by an alkaline solution to form a trench, a bottom of the trench is a second exposed surface 102 having a (111) crystal plane, and the (111) crystal plane is beneficial to subsequent epitaxial growth of the epitaxial layer 30.

Optionally, as shown in FIG. 4, a plane where the second exposed surface 102 is located is not parallel to a plane where the miscut angle substrate 10 is located. Specifically, the miscut angle substrate 10 is monocrystalline silicon, monocrystalline germanium or monocrystalline silicon germanium, the plane where the miscut angle substrate 10 is located has a miscut angle α deviating from the (111) crystal plane, and a crystal plane of the second exposed surface 102 is a (111) crystal plane. Therefore, an included angle between the plane where the miscut angle substrate 10 is located and the second exposed surface 102 is the miscut angle α, that is, the plane where the second exposed surface 102 is located is not parallel to the plane where the miscut angle substrate 10 is located.

In an embodiment, in a direction perpendicular to a plane where the miscut angle substrate 10 is located, a cross-sectional shape of the through hole 201 includes any one of a rectangle, a trapezoid, a parallelogram, and an irregular pentagon.

Optionally, as shown in FIG. 1, in a direction perpendicular to the plane where the miscut angle substrate 10 is located, a cross-sectional shape of the through hole 201 is rectangular, which may be formed by dry etching, and an etching direction is perpendicular to a plane where the mask layer 20 is located. As shown in FIG. 4, in a direction perpendicular to the plane where the miscut angle substrate 10 is located, the cross-sectional shape of the through hole 201 is an irregular pentagon, which may be obtained by adding an alkali liquor etching step to the through hole 201 shown in FIG. 1.

Optionally, FIG. 5 is a schematic structural diagram of a semiconductor structure according to another embodiment of the present disclosure, as shown in FIG. 5, in a direction perpendicular to a plane where the miscut angle substrate 10 is located, a cross-sectional shape of a through hole 201 is a trapezoid, and specifically, the cross-sectional shape of the through hole 201 is an isosceles trapezoid. Optionally, the cross-sectional shape of the through hole 201 is a right trapezoid (not shown). Optionally, due to a process error, the cross-sectional shape of the through hole 201 is a common trapezoid (not shown) with different bottom angles. Optionally, FIG. 6 is a schematic structural diagram of a semiconductor structure according to another embodiment of the present disclosure, and as shown in FIG. 6, in a direction perpendicular to a plane where the miscut angle substrate 10 is located, a cross-sectional shape of a through hole 201 is an irregular pentagon, which may be obtained by adding an alkali liquor etching step to the through hole 201 shown in FIG. 5.

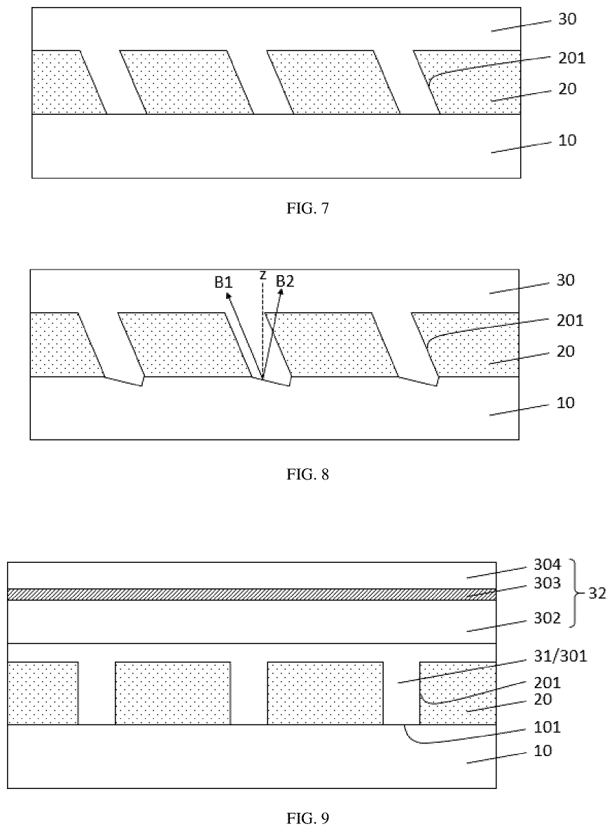

Optionally, FIG. 7 is a schematic structural diagram of a semiconductor structure according to another embodiment of the present disclosure, as shown in FIG. 7, in a direction perpendicular to a plane where the miscut angle substrate 10 is located, a cross-sectional shape of a through hole 201 is a parallelogram, which may be formed by dry etching, and an etching direction is not perpendicular to a plane where a mask layer 20 is located. Optionally, FIG. 8 is a schematic structural diagram of a semiconductor structure according to another embodiment of the present disclosure, as shown in FIG. 8, in a direction perpendicular to a plane where the miscut angle substrate 10 is located, a cross-sectional shape of a through hole 201 is an irregular pentagon, which may be obtained by adding an alkali liquor etching step to the through hole 201 shown in FIG. 7.

In an embodiment, as shown in FIG. 1, the extending direction of the through hole 201 is perpendicular to the plane where the miscut angle substrate 10 is located. Specifically, in the direction perpendicular to the plane where the miscut angle substrate 10 is located, the cross-sectional shape of the through hole 201 is rectangular.

In an embodiment, as shown in FIG. 8, an extending direction B1 of the through hole 201 and a crystal direction B2 of the miscut angle substrate 10 are located on different sides of a vertical axis z, and the vertical axis z is perpendicular to a plane where the miscut angle substrate 10 is located. Specifically, as shown in FIG. 8, dislocations extend along the crystal direction B2 of the miscut angle substrate 10, and are easier to be terminated at a sidewall of the through hole, thereby reducing a dislocation density of the semiconductor structure. If the extending direction of the through hole and the crystal direction of the miscut angle substrate are located on a same side of the vertical axis, that is, the dislocations are along the extending direction of the through hole, a probability that the dislocations can be terminated at the sidewall of the through hole is reduced, and a crystal quality of the semiconductor structure is not as good as a crystal quality of the semiconductor structure shown in FIG. 8.

In an embodiment, as shown in FIG. 1, the epitaxial layer 30 includes a first epitaxial layer 31 and a second epitaxial layer 32, the first epitaxial layer 31 is located in the through hole 201, and the second epitaxial layer 32 is located on a side, away from the miscut angle substrate 10, of the mask layer 20. Specifically, the first epitaxial layer 31 is first epitaxially formed at the through hole 201, and then on a side, away from the miscut angle substrate 10, of the mask layer 20, the second epitaxial layer 32 is formed by lateral epitaxy and healing of the first epitaxial layer 31. The dislocations may also be further reduced by a process of lateral epitaxy of the first epitaxial layer 31.

In an embodiment, FIG. 9 is a schematic structural diagram of a semiconductor structure according to another embodiment of the present disclosure, and as shown in FIG. 9, in a direction pointing from a miscut angle substrate 10 to a mask layer 20, a second epitaxial layer 32 includes: an N-type semiconductor layer 302, an active layer 303 and a P-type semiconductor layer 304 that are stacked in sequence. Specifically, the N-type semiconductor layer 302, the active layer 303 and the P-type semiconductor layer 304 manufactured on the mask layer 20 have a lower dislocation density, and thus a crystal quality of the semiconductor structure may be improved to improve a aluminous efficiency of a finally manufactured light-emitting device.

Optionally, taking a second epitaxial layer 32 as an example, the second epitaxial layer 32 is a GaN-based material, the N-type semiconductor layer 302 is an N-type GaN, the active layer 303 is a multi-quantum well layer composed of GaN and GaN-based ternary or quaternary compounds, and the P-type semiconductor layer 304 is a P-type GaN. Optionally, as shown in FIG. 9, a first epitaxial layer 31 includes a buffer layer 301, and the buffer layer 301 is configured to heal the epitaxial layer into a flat surface, thereby facilitating subsequent manufacture of a flat semiconductor film layer. Optionally, the first epitaxial layer 31 includes a nucleation layer and a buffer layer. Optionally, an electrode structure is not illustrated in FIG. 9, and the semiconductor structure may be an intermediate structure for manufacturing a light-emitting device.

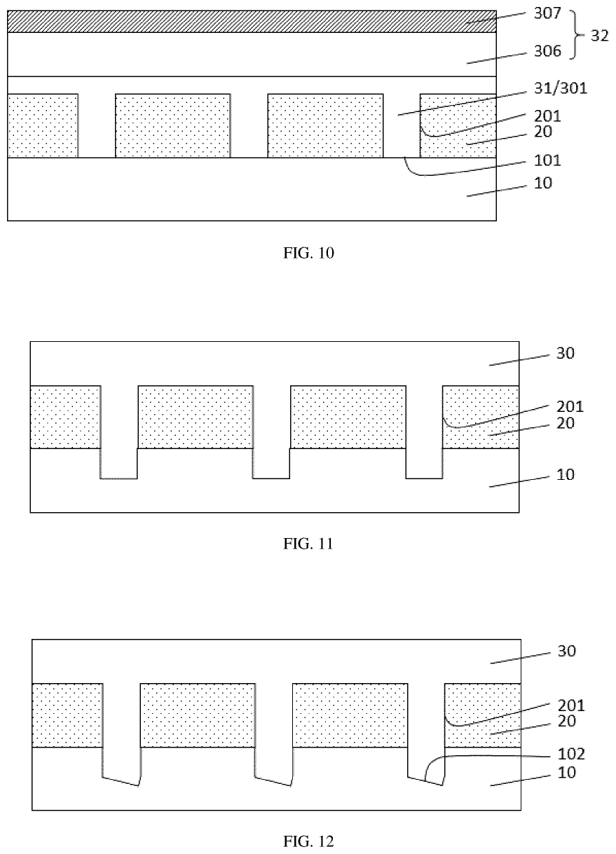

In an embodiment, FIG. 10 is a schematic structural diagram of a semiconductor structure according to another embodiment of the present disclosure, and as shown in FIG. 10, in a direction pointing from a miscut angle substrate 10 to a mask layer 20, a second epitaxial layer 32 includes: a channel layer 306 and a barrier layer 307 that are stacked in sequence. Specifically, the channel layer 306 and the barrier layer 307 manufactured on the mask layer 20 have a low dislocation density, which may improve a crystal quality of the semiconductor structure, so as to improve a power efficiency of a finally manufactured power device.

Optionally, taking a second epitaxial layer 32 as an example, the second epitaxial layer 32 is a GaN-based material, the channel layer 306 is GaN, and the barrier layer 307 is AlGaN. Optionally, as shown in FIG. 10, a first epitaxial layer 31 includes a buffer layer 301, and the buffer layer 301 is configured to heal the epitaxial layer into a flat surface, thereby facilitating subsequent manufacture of a flat semiconductor film layer. Optionally, the first epitaxial layer 31 includes a nucleation layer and a buffer layer.

In an embodiment, FIG. 11 is a schematic structural diagram of a semiconductor structure according to another embodiment of the present disclosure, as shown in FIG. 11, a through hole 201 of a mask layer 20 extends into an interior of a miscut angle substrate 10, a trench is formed on a surface of the miscut angle substrate 10, and a bottom of the trench is a crystal plane with a miscut angle. During an epitaxy process, an epitaxial layer 30 first fills the trench of the miscut angle substrate 10, and then fills the through hole 201 located in the mask layer 20. Optionally, as shown in FIG. 11, both the through hole 201 located in the mask layer 20 and a sidewall of the trench are perpendicular to a plane where the miscut angle substrate 10 is located.

Optionally, FIG. 12 is a schematic structural diagram of a semiconductor structure according to another embodiment of the present disclosure, and as shown in FIG. 12, when a miscut angle substrate 10 is monocrystalline silicon, monocrystalline germanium or monocrystalline silicon germanium, a trench formed on a surface of the miscut angle substrate 10 is subjected to an alkaline solution treatment to form a second exposed surface 102 having a (111) crystal plane.

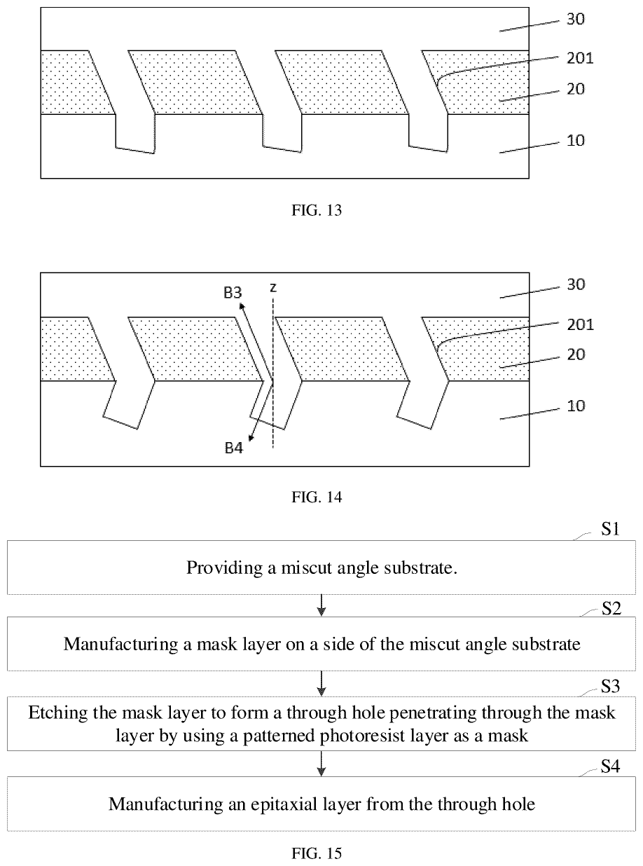

Optionally, FIG. 13 is a schematic structural diagram of a semiconductor structure according to another embodiment of the present disclosure, as shown in FIG. 13, an extending direction of a through hole 201 of a mask layer 20 is not perpendicular to a plane where a miscut angle substrate 10 is located, and an in-depth direction of the trench on a surface of the miscut angle substrate 10 is perpendicular to the plane where the miscut angle substrate 10 is located, that is, the extending direction of the through hole 201 of the mask layer 20 is different from the in-depth direction of the trench on the surface of the miscut angle substrate 10.

It should be noted that, as shown in FIG. 13, when the miscut angle substrate 10 is monocrystalline silicon, monocrystalline germanium or monocrystalline silicon germanium, the trench formed on the surface of the miscut angle substrate 10 is subjected to an alkaline solution treatment, and a second exposed surface having a (111) crystal plane is formed at a bottom of the trench.

Optionally, FIG. 14 is a schematic structural diagram of a semiconductor structure according to another embodiment of the present disclosure, as shown in FIG. 14, an upward extending direction B3 of a through hole 201 and a downward in-depth direction B4 of a trench on a surface of a miscut angle substrate 10 are located on a same side of a vertical axis z, dislocations may be terminated by a sidewall of the through hole 201, and an effect of reducing the dislocations is better.

It should be noted that, as shown in FIG. 14, when the miscut angle substrate 10 is monocrystalline silicon, monocrystalline germanium or monocrystalline silicon germanium, the trench formed on the surface of the miscut angle substrate 10 is subjected to an alkaline solution treatment, and a second exposed surface having a (111) crystal plane is formed at a bottom of the trench.

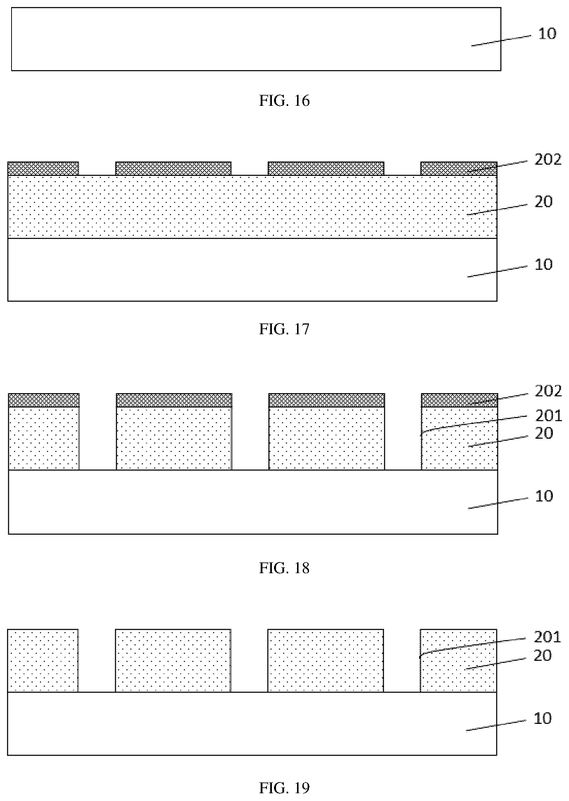

An embodiment of the present disclosure further provides a manufacturing method for a semiconductor structure, FIG. 15 is a schematic flowchart of a manufacturing method for a semiconductor structure according to an embodiment of the present disclosure, and FIG. 16 to FIG. 19 are schematic structural diagrams of intermediate structures in a manufacturing method for a semiconductor structure according to an embodiment of the present disclosure. As shown in FIG. 16 to FIG. 19, the manufacturing method includes following contents.

Step S1, as shown in FIG. 16, providing a miscut angle substrate 10. Optionally, the miscut angle substrate is any one of monocrystalline silicon, monocrystalline germanium, monocrystalline silicon germanium, monocrystalline silicon carbide, and sapphire. Specifically, the miscut angle substrate 10 may be commercially available, or may be a substrate that obtains a specific crystal plane, and then a miscut angle α may be obtained by performing miscut. The miscut angle α ranges from 0.1 degrees to 20 degrees. Further, the miscut angle α ranges from 0.2 degrees to 8 degrees.

Step S2, as shown in FIG. 17, manufacturing a mask layer 20 on a side of the miscut angle substrate 10. Optionally, a material of the mask layer 20 is SiO₂ or SiN. Optionally, a patterned photoresist layer 202 is manufactured above the mask layer 20.

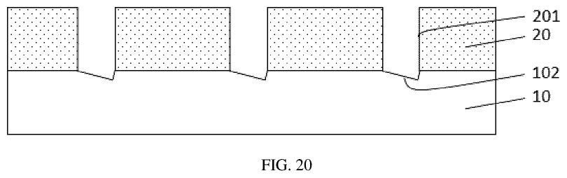

Step S3, as shown in FIG. 18, etching the mask layer 20 to form a through hole 201 penetrating through the mask layer 20 by using a patterned photoresist layer 202 as a mask. Optionally, as shown in FIG. 19, the photoresist layer 202 is removed.

Step S4, as shown in FIG. 1, manufacturing an epitaxial layer 30 from the through hole 201. Specifically, during an epitaxy process, a dislocation A gradually deviates from an extending direction of the through hole and is terminated at a sidewall of the through hole, so that a dislocation density of the semiconductor structure is reduced, and a crystal quality of a final semiconductor structure is relatively high.

Optionally, as shown in FIG. 1, in the through hole 201, the first epitaxial layer 31 is first epitaxially formed, when the first epitaxial layer 31 reaches a height at which an upper surface of the mask layer 20 is located, the second epitaxial layer 32 is formed by lateral epitaxy and healing of the first epitaxial layer 31, and finally, an upper surface of the semiconductor structure is a flat structure.

In an embodiment, as shown in FIG. 20, the miscut angle substrate 10 is monocrystalline silicon, monocrystalline germanium or monocrystalline silicon germanium, and before the epitaxial layer 30 is manufactured, the manufacturing method further includes: in the through hole 201, performing a wet etching, by using an alkaline solution, on the miscut angle substrate 10 to form a second exposed surface 102 exposed by the through hole 201, where a crystal plane of the second exposed surface 102 is a (111) crystal plane. Specifically, for example, due to the anisotropy of monocrystalline silicon, etching rates of different crystal directions of monocrystalline silicon in the alkaline solution are different, the monocrystalline silicon is etched by using a KOH solution, anisotropic V-type etching occurs, and a (111) crystal plane is obtained. The (111) crystal plane is more beneficial to epitaxial growth of an epitaxial structure layer (for example, an epitaxial structure layer of a group III-V compound material).

Embodiments of the present disclosure provide a semiconductor structure and a manufacturing method therefor. The semiconductor structure includes: a miscut angle substrate and a mask layer located on a side of the miscut angle substrate, where the mask layer includes a through hole penetrating through the mask layer, and at least part of an epitaxial layer is located in the through hole. The epitaxial layer is epitaxially grown on the miscut angle substrate exposed from the through hole, a part of dislocations in the epitaxial layer deviate from an extending direction of the through hole and are terminated at a sidewall of the through hole, thereby reducing a dislocation density of the semiconductor structure, improving a crystal quality, and improving characteristics of a semiconductor device.

It should be understood that the term “including” and its modification used in this disclosure are open-ended, that is, “including but not limited to”. The term “an embodiment” represents “at least one embodiment”. In this specification, specific features, structures, materials, or characteristics described may be incorporated in an appropriate manner in any one or more embodiments or examples. In addition, without being contradictory, a person skilled in the art may combine and permutate different embodiments or examples described in this specification and features of different embodiments or examples.

What is claimed is:

1. A semiconductor structure, comprising:
a miscut angle substrate;
a mask layer located on a side of the miscut angle substrate, wherein the mask layer comprises a through hole penetrating through the mask layer; and
an epitaxial layer, wherein at least part of the epitaxial layer is located in the through hole.

2. The semiconductor structure according to claim 1, wherein the miscut angle substrate comprises a first exposed surface exposed by the through hole, the first exposed surface has a miscut angle, and the miscut angle ranges from 0.1 degrees to 20 degrees.

3. The semiconductor structure according to claim 1, wherein the miscut angle ranges from 0.2 degrees to 8 degrees.

4. The semiconductor structure according to claim 2, wherein when the miscut angle substrate is monocrystalline silicon, monocrystalline germanium or monocrystalline silicon germanium, the first exposed surface has the miscut angle deviating from a (111) crystal plane.

5. The semiconductor structure according to claim 2, wherein when the miscut angle substrate is monocrystalline silicon carbide or sapphire, the first exposed surface has the miscut angle deviating from the (0001) crystal plane.

6. The semiconductor structure according to claim 1, wherein the miscut angle substrate is monocrystalline silicon, monocrystalline germanium or monocrystalline silicon germanium, the miscut angle substrate comprises a second exposed surface exposed by the through hole, and a crystal plane of the second exposed surface is a (111) crystal plane.

7. The semiconductor structure according to claim 6, wherein a plane where the second exposed surface is located is not parallel to a plane where the miscut angle substrate is located.

8. The semiconductor structure according to claim 1, wherein an extending direction of the through hole is perpendicular to a plane where the miscut angle substrate is located.

9. The semiconductor structure according to claim 1, wherein an extending direction of the through hole and a crystal direction of the miscut angle substrate are located on different sides of a vertical axis, and the vertical axis is perpendicular to a plane where the miscut angle substrate is located.

10. The semiconductor structure according to claim 1, wherein the epitaxial layer comprises a first epitaxial layer and a second epitaxial layer, the first epitaxial layer is located in the through hole, and the second epitaxial layer is located on a side, away from the miscut angle substrate, of the mask layer.

11. The semiconductor structure according to claim 10, wherein in a direction pointing from the miscut angle substrate to the mask layer, the second epitaxial layer comprises: an N-type semiconductor layer, an active layer, and a P-type semiconductor layer that are stacked in sequence.

12. The semiconductor structure according to claim 10, wherein in a direction pointing from the miscut angle substrate to the mask layer, the second epitaxial layer comprises: a channel layer and a barrier layer that are stacked in sequence.

13. The semiconductor structure according to claim 1, wherein the through hole extends into an interior of the miscut angle substrate, a trench is formed on a surface of the miscut angle substrate, and a bottom of the trench is a crystal plane with a miscut angle.

14. The semiconductor structure according to claim 13, wherein the miscut angle substrate is monocrystalline silicon, monocrystalline germanium or monocrystalline silicon germanium, the miscut angle substrate comprises a second exposed surface exposed by the trench, and a crystal plane of the second exposed surface is a (111) crystal plane.

15. The semiconductor structure according to claim 13, wherein an extending direction of the through hole is not perpendicular to a plane where the miscut angle substrate is located, and an in-depth direction of the trench is perpendicular to the plane where the miscut angle substrate is located.

16. The semiconductor structure according to claim 13, wherein an upward extending direction of the through hole and a downward in-depth direction of the trench are located on a same side of a vertical axis, and the vertical axis is perpendicular to a plane where the miscut angle substrate is located.

17. The semiconductor structure according to claim 1, wherein in a direction perpendicular to a plane where the miscut angle substrate is located, a cross-sectional shape of the through hole comprises any one of a rectangle, a trapezoid, a parallelogram, and an irregular pentagon.

18. The semiconductor structure according to claim 1, wherein a material of the mask layer comprises SiO₂ or SiN.

19. A manufacturing method for a semiconductor structure, comprising:
manufacturing a mask layer on a side of a miscut angle substrate;
etching the mask layer to form a through hole penetrating through the mask layer; and
manufacturing an epitaxial layer from the through hole.

20. The manufacturing method according to claim 19, wherein the miscut angle substrate is monocrystalline silicon, monocrystalline germanium or monocrystalline silicon germanium, and before the epitaxial layer is manufactured, the manufacturing method further comprises:
in the through hole, performing a wet etching, by using an alkaline solution, on the miscut angle substrate to form a second exposed surface exposed by the through hole, wherein a crystal plane of the second exposed surface is a (111) crystal plane.
